(19) United States
(12) Patent Application Publication
(10) Pub. No.: US 2008/0081424 A1
(43) Pub. Date: Apr. 3, 2008

(54) Method of production of a semiconductor memory device and semiconductor memory device

(76) Inventors: Josef Willer, Riemerling (DE); Karl-Heinz Kuesters, Boxdorf (DE)

Correspondence Address: SLATER & MATSIL LLP, 17950 PRESTON ROAD, SUITE 1000, DALLAS, TX, 75252, US

(21) Appl. No.: 11/541,458

(22) Filed: Sep. 29, 2006

(51) Int. Cl. H01L 21/336

(52) U.S. Cl. 438/299

(57) ABSTRACT

A layer of electrically conductive material is applied above a carrier surface. Gate electrodes are formed above a first area of the carrier surface from the electrically conductive material. An implantation of a dopant that is provided for source/drain regions is performed in the first area. The implant is annealed, and an auxiliary layer of a dielectric material is applied to planarize the surface. The first area is covered with a mask, and a further implantation of a dopant provided for source/drain regions is performed in a second area of the carrier surface provided for a memory cell array. The implant is annealed, and the memory cells are formed in the second area. The semiconductor memory device may comprise a selectively deposited electrically conductive material on the gate electrodes of the periphery and on buried bitlines of the memory cell array.

### TECHNICAL FIELD

This invention is related to semiconductor memory devices, especially multi-bit charge-trapping memory devices, including a memory cell array and an addressing periphery, and methods of production of these memory devices.

### BACKGROUND

German Patent No. 10110150, and corresponding U.S. Patent Publication No. 2002/0132430, describe a memory device with charge-trapping layers, which can be fabricated together with transistors of an addressing periphery. The described production method is applied to a virtual-ground NOR array. A conventional shallow trench isolation module is used. Wells are implanted, and the charge-trapping layers are grown. Additionally, different gate oxides can be formed for different types of transistors. First layers of the gate stacks are deposited and patterned to obtain buried bitline openings in the area that is provided for the memory cell array. Buried bitlines and source/drain regions of the memory cell transistors are implanted through the openings, and the implants are subsequently annealed. The openings are filled, and the surface is planarized. Second gate layers are deposited and patterned to form gates in the area of the array and in the periphery. Junctions of CMOS transistors are formed in the periphery by a further implantation. The implants are annealed, and standard backend process steps follow.

The source/drain regions of the memory cell transistors are implanted before the implantation of the source/drain regions of the peripheral transistors takes place. Therefore, the implantation in the periphery has to be annealed when the doping atoms are already present in the memory cell array and are subject to an enhanced diffusion due to the comparably large thermal budget of the annealing step. Thus it is not possible to realize a sufficiently small, preferably minimal, thermal budget for the memory cell transistors, which are the devices that are shrunk to the smallest structural dimensions. A further miniaturization and improved scalability cannot be obtained without adapting the thermal budget to the requirements of the memory cell transistors. But there is a lower limit to the thermal budget due to the requirements of the peripheral transistors.

### SUMMARY OF THE INVENTION

In one embodiment of forming a semiconductor memory device, a layer of electrically conductive material is applied above a carrier surface. Gate electrodes are formed from the layer of electrically conductive material above a first area of the carrier surface. An implantation of a dopant provided for source/drain regions is performed in the first area. The implant is annealed. An auxiliary layer of dielectric material is applied. The surface is planarized. The first area is covered with a mask. A further implantation of a dopant provided for source/drain regions in a second area of the carrier surface is performed. The implant is annealed, and an array of memory cells is formed in the second area.

These and other features of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of an intermediate product of an embodiment after the application of the storage layer;

FIG. 2 shows a cross-section according to FIG. 1 after the application of a layer of electrically conductive material and a hardmask layer;

FIG. 3 shows the arrangement of the first hardmask and the active area in the addressing periphery;

FIG. 4 shows a section of a plan view of the memory cell area;

FIG. 5 shows a cross-section according to FIG. 2 after the application of a first auxiliary layer planarizing the surface;

FIG. 6 shows a cross-section according to FIG. 5 of an alternative embodiment;

FIG. 7 shows a cross-section according to FIG. 5 or 6 after the formation of openings in the layer of electrically conductive material in the memory cell area;

FIG. 8 shows a plan view of the memory cell area of the intermediate product of FIG. 7;

FIG. 9 shows a cross-section according to FIG. 7 after the application of a second auxiliary layer;

FIG. 10 shows a cross-section according to FIG. 9 of an alternative embodiment with thin sidewall spacers;

FIG. 11 shows a cross-section according to FIG. 9 or 10 after the application of a wordline layer sequence;

FIG. 12 shows a cross-section perpendicular to the cross-section of FIG. 11 after the formation of wordline stacks;

FIG. 13 shows a plan view of the arrangement of the wordline stacks;

FIG. 14 shows a cross-section according to FIG. 11 after the application of an intermetal dielectric;

FIG. 15 shows a cross-section according to FIG. 11 of a further embodiment;

FIG. 16 shows a cross-section according to FIG. 15 after the application of an intermetal dielectric; and

FIG. 17 shows a cross-section according to FIG. 10 of a further embodiment.

### DETAILED DESCRIPTION OF ILLUSTRATIVE EMBODIMENTS

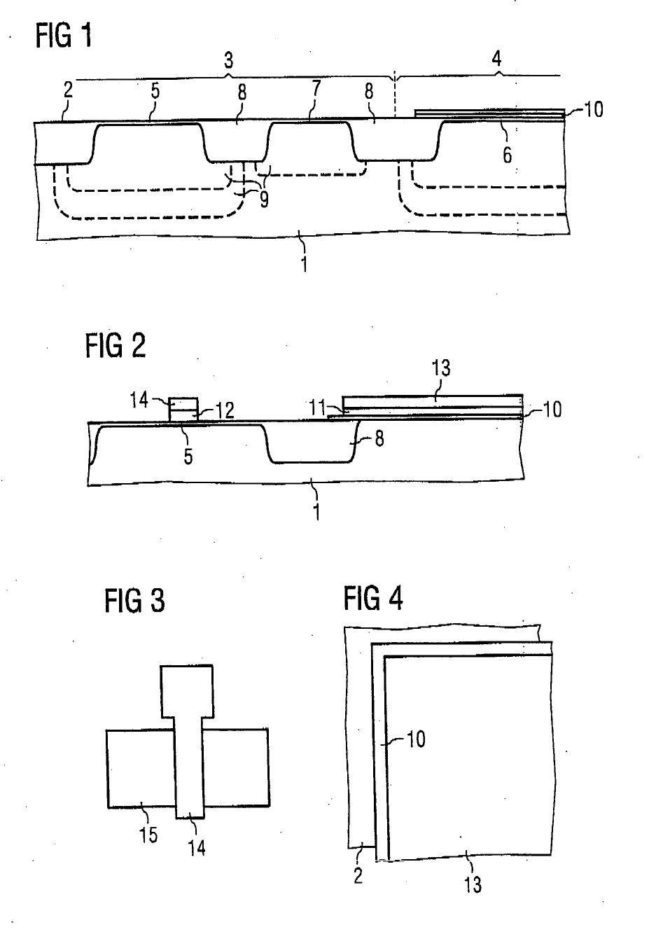

FIG. 1 shows a cross-section of a carrier 1, which can be a semiconductor body, such as a bulk silicon substrate, after the first process steps of a first example of the method. The carrier surface 2 is provided for a first area 3, where the periphery devices are to be arranged, and a second area 4, where the memory cell array is to be formed. A first dielectric 5, which is provided for the gate dielectric of transistors, is formed on the carrier surface 2 in the first area 3. A second dielectric 6 is formed in the second area 4. Further dielectric layers, which are provided for different types of transistors, can additionally be provided, for example the third dielectric 7 shown in FIG. 1 in the first area 3.

The active transistor areas are isolated by isolation regions 8, which can be field isolations or shallow trench isolations, for example. The isolation regions 8 can be formed in a conventional manner by an application of a nitride hardmask, a reactive ion etching of the carrier material, an optional application of a liner, an application of an oxide filling, and a planarization by CMP (chemical mechanical polishing). The gate dielectrics are preferably formed after the formation of the isolation regions 8. Suitable wells 9 are formed by implantations in a manner known per se from standard CMOS processes, for example.

Above the second area 4, a storage layer 10 or storage layer sequence can be applied for the memory cell transistors, especially a storage layer of a dielectric material that is suitable for charge-trapping. FIG. 1 shows the cross-section of the intermediate product that is obtained so far.

FIG. 2 shows a further intermediate product in a cross-section according to FIG. 1. A layer of electrically conductive material 11 is deposited, which can be electrically conductively doped polysilicon, for example, which is provided for gate electrodes. A hardmask layer 13, which can be nitride, is applied onto the layer of electrically conductive material 11. The hardmask layer 13 is structured to form a first hardmask 14 above the first area 3 of the carrier surface 2. The first hardmask 14 is patterned according to the gate structures that are provided for the periphery devices. During the patterning of the hardmask, the second area 4 is covered, for instance by a resist layer. The patterning of the hardmask layer 13 can be achieved in a conventional way by a standard lithography step. The structure of the first hardmask 14 is etched into the layer of electrically conductive material 11 to form the gate electrode 12.

FIG. 3 shows a plan view of the first hardmask 14 above the active area 15 that is provided for one of the peripheral transistors shown as an example.

FIG. 4 shows a plan view of the second area 4 of the carrier surface 2 with the entire hardmask layer 13, which in this example does not completely cover the storage layer 10.

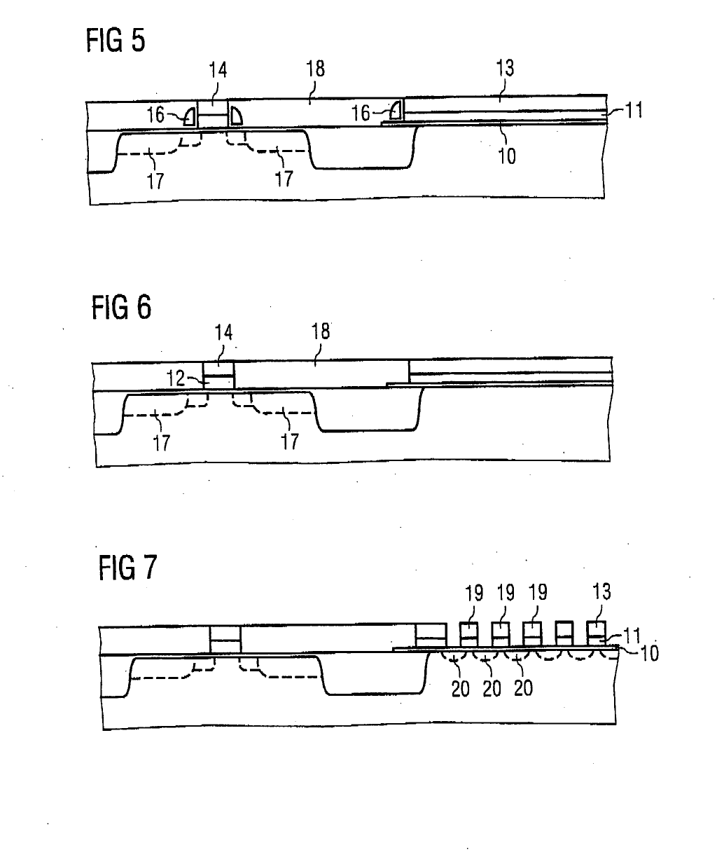

FIG. 5 shows a cross-section according to FIG. 2 after the application of sidewall spacers 16 and the implantation of source/drain regions 17. In this manner, source/drain junctions of various CMOS devices can be produced by conventional implantation and anneal steps, utilizing appropriate liner/spacer combinations. FIG. 5 shows only one typical example. Then the first auxiliary layer 18 is applied on the first area, and the surface is planarized. The planarization can be effected by CMP, which stops approximately on the upper surface of the first hardmask 14.

FIG. 6 shows a cross-section according to FIG. 5 for another embodiment, in which the sidewall spacers 16 have been removed before the application of the first auxiliary layer 18.

The cross-sections of FIG. 5 and FIG. 6 show an essential feature of this method. The formation of the source/drain junctions of the peripheral transistors and the memory cell transistors in reversed order as compared to prior art is made possible by the planarization of the device surface after the formation of the gate stacks in the periphery and the implantation of the source/drain regions 17 in the first area 3.

FIG. 7 shows a cross-section according to FIG. 6 after a patterning of the layer of electrically conductive material 11 above the second area 4. This can be achieved by a conventional lithography step, by which the hardmask layer 13 is patterned into a second hardmask 19. The second hardmask 19 and the layer of electrically conductive material 11 can be structured by reactive ion etching, for example. The storage layer 10 can be maintained in the openings, or can be more or less removed. Then, preferably, a halo implant is applied, which is intended for the buried bitlines 20.

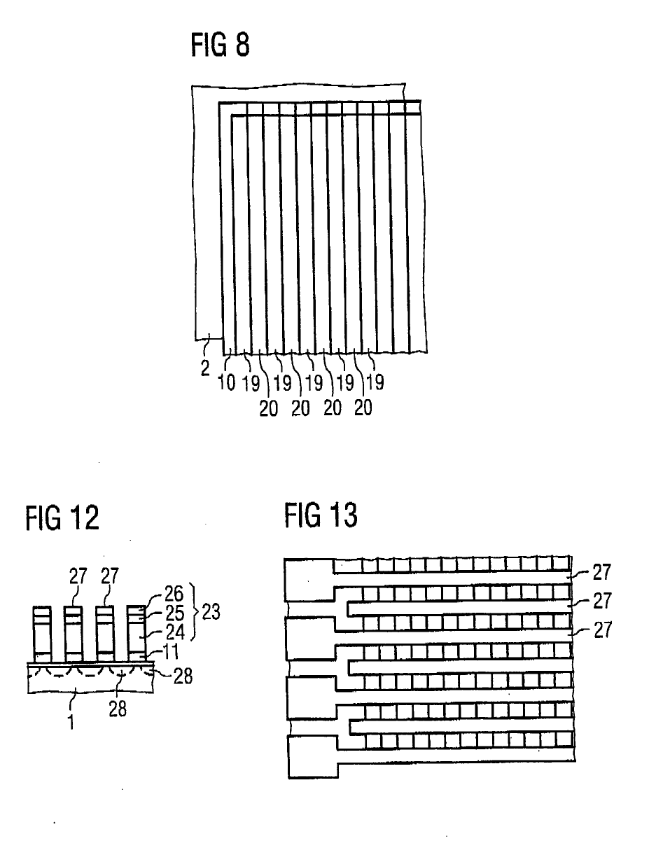

FIG. 8 shows a plan view of the second area 4, indicating the relative positions of the striplike sections of the second hardmask 19 and the areas of the buried bitlines 20.

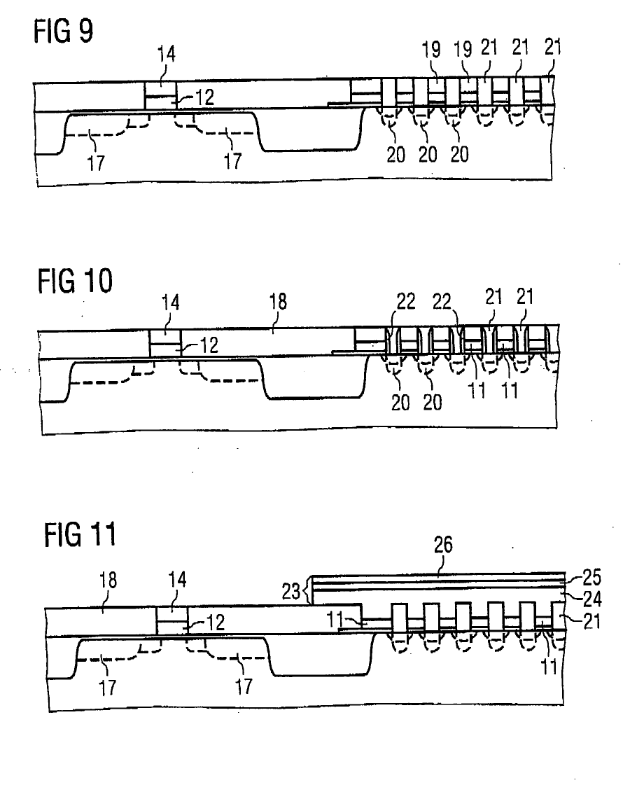

FIG. 9 shows a cross-section according to FIG. 7 after the complete implantation of the buried bitlines 20, which encompass the source/drain regions of the individual memory cell transistors. A typical implantation, which is appropriate here, uses arsenic as the dopant, which is introduced at a dose of more than 10¹⁵/cm². The annealing is performed at typically 1000° C. to 1050° C. for at most five seconds. The openings are then filled with the second auxiliary layer 21 of dielectric material. The surface is again planarized. This can again be effected by CMP, stopping on the hardmasks 14, 19.

FIG. 10 shows another embodiment, which is provided with thin spacers 22 at the sidewalls of the striplike remaining portions of the layer of electrically conductive material 11 and, optionally, at the sidewalls of the second hardmask 19. These spacers 22 are preferably formed before the ultimate implantation of the buried bitlines 20. The second hardmask 19 is then removed from the second area 4. The first hardmask 14 is still present above the first area 3. It is covered by a suitable mask when the second hardmask 19 is removed.

FIG. 11 shows a cross-section according to FIG. 9 after the application of a wordline layer sequence 23. The wordline layer sequence 23 can encompass a wordline polysilicon layer 24, contact-connecting the remaining portions of the layer of electrically conductive material 11, which are provided as gate electrodes of the memory cell transistors, a wordline metal layer 25, which can be tungsten or tungsten silicide, for example, and a wordline hardmask layer 26, which can be nitride, for example.

FIG. 12 shows a cross-section perpendicular to the cross-section of FIG. 11 after the patterning of the wordline layer sequence 23 and the layer of electrically conductive material 11 into wordline stacks 27. This can preferably be effected by a conventional lithography step and subsequent RIE (reactive ion etching), stopping on the storage layer 10. A channel stop implant 28 is introduced between the gates to isolate the individual memory cells from one another.

FIG. 13 shows a plan view of the second area 4 indicating the arrangement of the wordline stacks 27.

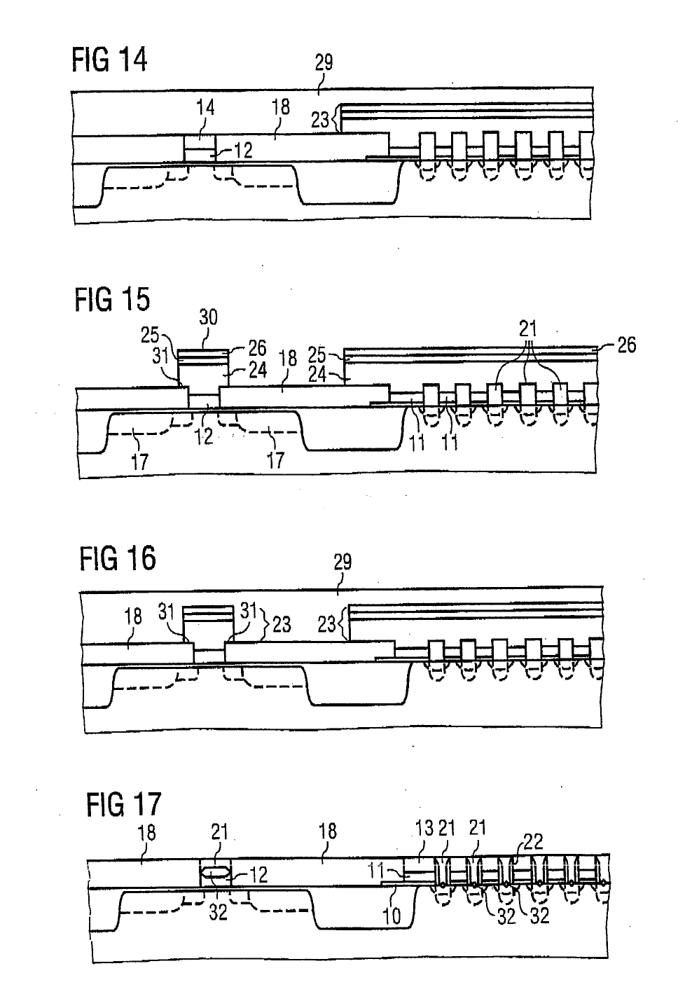

FIG. 14 shows a cross-section according to FIG. 11 after the application of an intermetal dielectric 29, which fills the gaps between the wordline stacks. The intermetal dielectric 29 can be oxide or another material having a low dielectric constant. The surface is again planarized, for instance by CMP. Subsequent process steps can include the application of one or several types of contacts to the carrier, the wordlines, and the gate polysilicon of the CMOS devices. The latter contacts are unique to this method of production, because the gate electrodes of the peripheral transistors have been produced before the memory cell array. Further, several metal levels including intermetal dielectrics and vias as well as passivations are applied. This can be done according to conventional manufacturing processes.

FIG. 15 shows a cross-section according to FIG. 11 of a further embodiment. In this embodiment, the first hardmask 14 is removed together with the second hardmask 19, before the wordline layer sequence 23 is applied. The wordline layer sequence 23 is in this case used as a contact and electric connection to the gate electrode 12 of the peripheral transistor and forms a gate electrode stack 30. As shown in FIG. 15, the wordline layer sequence 23, in this example encompassing a wordline polysilicon layer 24, a wordline metal layer 25, and a wordline hardmask layer 26, shows an overhang structure 31 above the edges of the gate electrode 12. This means that the wordline layer sequence laterally exceeds the gate electrode 12, so that marginal sections of the wordline layer sequence are located on the laterally adjacent first auxiliary layer 18.

FIG. 16 shows a cross-section according to FIG. 15 after the application of the intermetal dielectric 29 in a manner that is similar to the one that has already been described in conjunction with FIG. 14.

FIG. 17 shows a cross-section according to FIG. 10 of a further embodiment. In this embodiment, after the implantation of the buried bitlines, optionally after the application of thin spacers 22, the first hardmask 14 is removed from the gate electrodes 12 in the periphery. This can again be performed by a lithography step. An electrically conductive material 32 is selectively deposited on the gate electrode 12 and the buried bitlines. This material can include a metal like cobalt, by which a salicidation (self-aligned silicidation) is formed, which is CoSi in the example using cobalt. The second auxiliary layer 21 is then applied also above the gate electrode 12 to cover the electrically conductive material 32. The contact of the gate electrode 12 in this embodiment is of the same type as the contact on the electrically conductive material on the buried bitlines.

The described methods are especially favorably applicable to multi-bit charge-trapping memory devices, in particular to a class of memory arrays in which the current passing the cells is directed parallel to the wordlines. The disclosed integration concept improves the scalability by minimizing the junction diffusion of the memory cell transistors. Although the properties of a virtual-ground array require process steps that are different for the cell transistors and the addressing CMOS devices, and the annealing steps differ accordingly, this does not cause any drawbacks since the memory cell junctions are annealed at the latest possible stage of the fabrication process. Thus, the thermal budget which the memory cell transistors are subjected to can be minimized. This is made possible by activating the cell junctions after the major processing of the peripheral devices. The lateral diffusion of the n⁺-junctions of the cell transistors can thus be confined to a distance of less than 10 nm.

Although the present invention and its advantages have been described in detail, it should be understood that various changes, substitutions and alterations can be made herein without departing from the spirit and scope of the invention as defined by the appended claims.

What is claimed is:

1. A method of producing a semiconductor memory device, the method comprising:
applying a layer of electrically conductive material above a carrier surface;
forming gate electrodes from said layer of electrically conductive material, the gate electrodes being formed over a first area of the carrier surface;
performing an implantation of a dopant to form source/drain regions in the first area;
annealing the implant;
applying an auxiliary layer of dielectric material;
planarizing a surface of the auxiliary layer of dielectric material;
covering the first area with a mask;
performing a further implantation of a dopant to form source/drain regions in a second area of the carrier surface;
annealing the implant; and
forming an array of memory cells in the second area.

2. The method according to claim 1, wherein forming the gate electrodes comprises forming the gate electrodes using a hardmask.

3. The method according to claim 2, wherein said hardmask is left on the gate electrodes when the surface is planarized.

4. The method according to claim 3, wherein the planarizing stops on the hardmask.

5. The method of producing of a semiconductor memory device, the method comprising:
forming a first gate dielectric above a first area of a carrier surface and a second gate dielectric above a second area of said carrier surface;
applying a layer of electrically conductive material;
applying a hardmask layer over the layer of electrically conductive material;
structuring said hardmask layer into a hardmask above said first area;
forming gate electrodes above the first area by structuring said layer of electrically conductive material using said hardmask as a mask;
performing an implantation of a dopant to form source/drain regions in the first area;
annealing the implant;
applying an auxiliary layer of dielectric material;
planarizing a surface of the auxiliary layer of dielectric material;
covering the first area with a mask; and
forming an array of memory cells in the second area.

6. The method according to claim 5, wherein forming the array of memory cells comprises:
patterning said hardmask layer into a second hardmask above said second area;
patterning said layer of electrically conductive material above the second area using the second hardmask;
performing an implantation of a dopant provided for source/drain regions of memory transistors and buried bitlines in the second area; and
annealing the implant.

7. The method according to claim 6, further comprising:
applying a further auxiliary layer of dielectric material;
planarizing a surface of the further auxiliary layer of dielectric material;
removing the second hardmask;
applying a wordline layer sequence; and
patterning said wordline layer sequence into wordline stacks.

8. The method according to claim 6, further comprising:
applying a further auxiliary layer of dielectric material;
planarizing a surface of the further auxiliary layer of dielectric material;
removing said hardmask layer;
applying a wordline layer sequence; and
patterning said wordline layer sequence into gate electrode stacks above the first area and into wordline stacks above the second area.

9. The method according to claim 6, further comprising:
removing the hardmask from the first area;
selectively depositing an electrically conductive material onto the gate electrodes above the first area and onto the implanted regions above the second area;
applying a further auxiliary layer of dielectric material;
planarizing a surface of the further auxiliary layer of dielectric material;
removing the second hardmask from the second area;
applying a wordline layer sequence; and
patterning said wordline layer sequence into wordline stacks.

10. The method according to claim 9, wherein the electrically conductive material forms silicide.

11. The method according to claim 10, wherein the electrically conductive material comprises cobalt to form CoSi.

12. The method according to claim 5, wherein forming an array of memory cells includes applying a storage layer that is suitable for charge-trapping above the second area.

13. A method of producing of a semiconductor memory device, the method comprising:
applying an electrically conductive layer above a carrier surface comprising a first area provided for an addressing periphery and a second area provided for a memory cell array;
applying a hardmask layer over the electrically conductive layer;
forming gate electrode stacks from said hardmask layer and said electrically conductive layer above said first area;
performing an implantation of a dopant to form source/drain regions in the first area, the source/drain regions self-aligned to the gate electrode stacks;
annealing the implant;
patterning said hardmask layer and said electrically conductive layer above said second area;
performing an implantation of a dopant to form source/drain regions and buried bitlines in the second area; and
annealing the implant.

14. The method according to claim 13, further comprising applying an auxiliary layer of dielectric material between the gate electrode stacks and planarizing a surface of the auxiliary layer of dielectric material.

15. The method according to claim 14, wherein planarizing the surface is effected to an upper surface level of the hardmask layer.

16. The method according to claim 13, further comprising applying a material that is suitable for charge-trapping above the second area before applying the electrically conductive layer.

17. A semiconductor memory device comprising:
a first area provided for an addressing periphery and a second area provided for an array of memory cells; and
gate electrodes above the first area, the gate electrodes comprising a selectively deposited electrically conductive material.

18. The semiconductor memory device according to claim 17, further comprising buried bitlines in the second area, the buried bitlines comprising a selectively deposited electrically conductive material.

19. The semiconductor memory device according to claim 18, wherein said selectively deposited electrically conductive material comprises a salicide.

20. The semiconductor memory device according to claim 19, wherein said selectively deposited electrically conductive material comprises CoSi.
